(19) United States
(12) Patent Application Publication
(10) Pub. No.: US 2024/0321604 A1
(43) Pub. Date: Sep. 26, 2024

(54) SEMICONDUCTOR MANUFACTURING DEVICE, AND SEPARATING MEMBER

(71) Applicant: Kioxia Corporation, Tokyo (JP)

(72) Inventor: Sho KAWADAHARA, Yokkaichi Mie (JP)

(21) Appl. No.: 18/588,521

(22) Filed: Feb. 27, 2024

(30) Foreign Application Priority Data
Mar. 20, 2023 (JP) 2023-043753

(51) Int. Cl. H01L 21/67; H01L 21/66; H01L 21/687

(52) U.S. Cl. CPC H01L 21/67092; H01L 21/67259; H01L 21/68771; H01L 22/26; H01L 21/68785

(57) ABSTRACT

A semiconductor manufacturing device includes a substrate supporting unit configured to place a bonded substrate including two substrates bonded to each other; an arm portion disposed next to the substrate supporting unit and configured to move toward and from a bonded portion of the bonded substrate; and a separating member provided on an end of the arm portion and configured to separate the two substrates by the arm portion entering the bonded portion, wherein the separating member includes a first inclined face and a second inclined face that extend toward the bonded portion and are respectively extended from end portions of first and second faces of the separating member. The separating member further includes an aperture portion configured to discharge a fluid toward the bonded portion.

### CROSS-REFERENCE TO RELATED APPLICATION (S)

This application is based upon and claims the benefit of priority from Japanese Patent Application No. 2023-043753, filed Mar. 20, 2023, the entire contents of which are incorporated herein by reference.

### FIELD

Embodiments described herein relate generally to a semiconductor manufacturing device, and to a separating member.

### BACKGROUND

During a semiconductor device manufacturing process or the like, a memory cell chip on which a memory cell array is to be formed and a substrate on which a control circuit that controls the memory cell array is formed may be bonded together. When the two substrates are bonded deviating from each other, a blade may be inserted between the two substrates, and the substrates separated.

When doing so, damage may be caused to the substrates due to the blade coming into contact with the substrates.

### DESCRIPTION OF THE DRAWINGS

FIG. 1 is a perspective top view schematically showing one example of an overall configuration of a semiconductor manufacturing device according to an embodiment.

FIG. 2 is a side view showing a detailed example of a configuration of a processing chamber provided in the semiconductor manufacturing device according to the embodiment.

FIG. 3 is a perspective view showing an example of a configuration of one portion of a separating arm unit provided in the semiconductor device manufacturing device according to the embodiment.

FIG. 4 is a top view showing an example of a configuration of one portion of the separating arm unit provided in the semiconductor device manufacturing device according to the embodiment.

FIG. 5 is a drawing illustrating an aspect such that a blade provided in the semiconductor manufacturing device according to the embodiment is interposed in a bonded portion.

FIG. 6A and FIG. 6B are a drawing sequentially showing an example of one portion of a procedure of a process of dividing a bonded substrate using the semiconductor manufacturing device according to the embodiment.

FIG. 7A and FIG. 7B are a drawing sequentially showing an example of one portion of a procedure of a process of dividing the bonded substrate using the semiconductor manufacturing device according to the embodiment.

FIG. 8A and FIG. 8B are a drawing sequentially showing an example of one portion of a procedure of a process of dividing the bonded substrate using the semiconductor manufacturing device according to the embodiment.

FIG. 9A and FIG. 9B are a drawing sequentially showing an example of one portion of a procedure of a process of dividing the bonded substrate using the semiconductor manufacturing device according to the embodiment.

FIG. 10A and FIG. 10B are a drawing sequentially showing an example of one portion of a procedure of a process of dividing the bonded substrate using the semiconductor manufacturing device according to the embodiment.

FIG. 11 is a top view showing one example of a configuration of a processing chamber provided in a semiconductor manufacturing device according to a modification.

### DETAILED DESCRIPTION

One embodiment provides a semiconductor manufacturing device and a separating member such that bonded substrates can be separated while restricting damage to the substrates.

In general, according to one embodiment, a semiconductor manufacturing device includes a substrate supporting unit configured to place a bonded substrate including two substrates bonded to each other; an arm portion disposed next to the substrate supporting unit and configured to move toward and from a bonded portion of the bonded substrate; and a separating member provided on an end of the arm portion and configured to separate the two substrates by the arm portion entering the bonded portion, wherein the separating member includes a first inclined face and a second inclined face that extend toward the bonded portion and are respectively extended from end portions of first and second faces of the separating member. The separating member further includes an aperture portion configured to discharge a fluid toward the bonded portion.

Hereafter, an embodiment will be described in detail, while referring to the drawings. The present disclosure is not limited by the following embodiment. Also, components obvious to those skilled in the art, or substantially identical components, are provided in components in the following embodiment.

### Substrate Separating Device Configuration Example

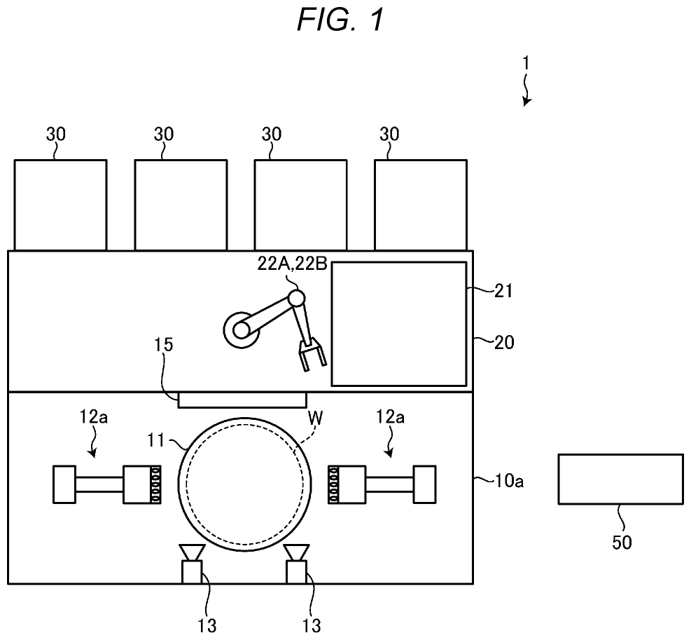

FIG. 1 is a perspective top view schematically showing one example of an overall configuration of a semiconductor manufacturing device 1 according to the embodiment.

The semiconductor manufacturing device 1 of the embodiment is configured as a substrate separating device that can divide a bonded substrate W, thereby disassembling the bonded substrate W into the two substrates configuring the bonded substrate W.

The bonded substrate W, which is a processing target of the semiconductor manufacturing device 1 of the embodiment, is formed by two substrates, on each of which a circuit element is formed and which are ground to a thickness of in the region of, for example, 1 mm, being bonded together in such a way that, for example, corresponding metal pads are electrically connected to each other.

After the substrates are bonded together, an inspection as to whether a positioning accuracy complies with a standard is carried out. When it is determined that the positioning accuracy fails, a separating process is carried out on the bonded substrate W using the semiconductor manufacturing device 1 according to the embodiment. The two substrates separated by the separating process are bonded together again after positioning.

As shown in FIG. 1, the semiconductor manufacturing device 1 of the embodiment includes a processing chamber 10a, a transfer chamber 20, a multiple of ports 30, and a control unit 50.

The processing chamber 10a is a space for carrying out a separating process on the bonded substrate W, which is a processing target. The bonded substrate W transferred to the processing chamber 10a from a loading port 15 is supported by a chuck unit 11. On a height alignment of the bonded substrate W and a separating arm unit 12a being carried out using a cleaving position adjustment side camera 13, one portion of the separating arm unit 12a moves toward a center of the chuck unit 11, and enters between bonded faces of the bonded substrate W. Because of this, the bonded substrate W is divided.

The transfer chamber 20 is a space for transferring the bonded substrate W and the two substrates whose separation is completed. The transfer chamber 20 is connected to the processing chamber 10a. The transfer chamber 20 has a pre-alignment unit 21 in which a positional adjustment of the bonded substrate W before processing is carried out, a transfer arm 22A that carries out a transfer of the bonded substrate W, and a transfer arm 22B that carries out a transfer of the two substrates whose separation is completed.

The pre-alignment unit 21 corrects a deviation of a central position of the bonded substrate W. The pre-alignment unit 21 includes an unshown light emitting unit and light receiving unit disposed, for example, in an up-down direction in a vicinity of an edge of the bonded substrate W. Owing to the edge of the bonded substrate W interrupting light between the light emitting unit and the light receiving unit, an amount of light detected in the light receiving unit changes, whereby the edge of the bonded substrate W is detected. The pre-alignment unit 21 transfers the bonded wafer W to the transfer arm 22A in a state after the deviation of the central position of the bonded substrate W is corrected based on the edge detection result.

The transfer arm 22A transfers the bonded substrate W to each portion of the semiconductor manufacturing device 1. The transfer arm 22A transfers the unprocessed bonded substrate W from the port 30 to the transfer chamber 20, from the transfer chamber 20 to the pre-alignment unit 21, and from the pre-alignment unit 21 to the processing chamber 10a.

The transfer arm 22B transfers the two separated substrates to each portion of the semiconductor manufacturing device 1. The transfer arm 22B transfers the two separated substrates from the processing chamber 10a to the transfer chamber 20, and from the transfer chamber 20 to the port 30.

The port 30 stores the bonded substrate W and the substrates whose separation is completed. The port 30 is connected to the transfer chamber 20. The port 30 is configured in such a way that a multiple of substrates can be housed therein.

The control unit 50 controls each portion of the semiconductor manufacturing device 1. The control unit (controller) 50 is configured as a computer that includes an unshown central processing unit (CPU) or processor, read-only memory (ROM), random-access memory (RAM), and the like, and controls a whole of the semiconductor manufacturing device 1.

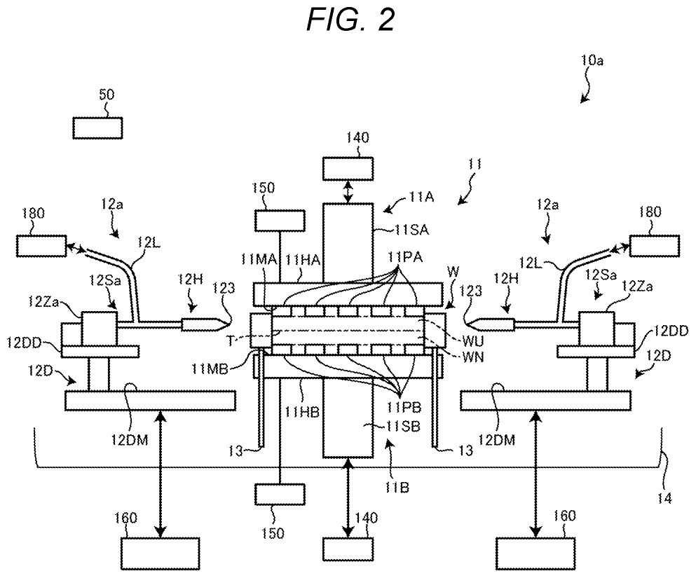

Next, using FIG. 2, an example of a configuration of the processing chamber 10a provided in the semiconductor manufacturing device 1 will be described in detail.

FIG. 2 is a side view showing a detailed example of a configuration of the processing chamber 10a provided in the semiconductor manufacturing device 1 according to the embodiment.

The processing chamber 10a has the chuck unit 11, the separating arm unit 12a, the cleaving position adjustment side camera 13, and a fluid recovery pan 14, as shown in FIG. 2, and the loading port 15. For ease of description, a depiction of the loading port 15 is omitted.

In the present specification, a direction perpendicular to the bonded substrate W supported by the chuck unit 11 is an up-down direction. In this case, a direction in which the fluid recovery pan 14 is disposed is a downward direction, and an opposite direction is an upward direction, as seen from the bonded substrate W.

The chuck unit 11 acting as a substrate supporting unit supports the bonded substrate W in which two substrates are bonded together in a bonded portion T. The bonded portion T is a portion in which a substrate WU and a substrate WN, which configure the bonded substrate W, are bonded together. The chuck unit 11 has an upper chuck 11A and a lower chuck 11B disposed separated in the up-down direction.

The upper chuck 11A is configured in a disc form as seen from above. The upper chuck 11A has a supporting portion 11SA and an adsorption pin holding member 11HA.

The adsorption pin holding member 11HA is such that a central portion thereof is supported from above by the supporting portion 11SA. The adsorption pin holding member 11HA has a downward-oriented adsorption pin holding face 11MA. A multiple of adsorption pins 11PA are provided on the adsorption pin holding face 11MA. The multiple of adsorption pins 11PA can come into contact with the substrate WU on an upper side of the bonded substrate W.

The lower chuck 11B is configured in a disc form as seen from below. The lower chuck 11B has a supporting portion 11SB and an adsorption pin holding member 11HB.

The adsorption pin holding member 11HB is such that a central portion thereof is supported from below by the supporting portion 11SB. The absorption pin holding member 11HB has an adsorption pin holding face 11MB that is oriented upward and opposes the adsorption pin holding face 11MA. A multiple of adsorption pins 11PB are provided on the adsorption pin holding face 11MB. The multiple of adsorption pins 11PB can come contact with the substrate WN on a lower side of the bonded substrate W.

The adsorption pins 11PA and 11PB are provided to be, for example, arrayed around a number of imaginary concentric circles on the adsorption pin holding faces 11MA and 11MB respectively. Each of the adsorption pins 11PA and 11PB has, for example, a cylindrical form, and an inner tube (not shown) is formed along a central axis of the cylinder. The inner tube communicates with a conduit (not shown) formed in an interior of the adsorption pin holding members 11HA and 11HB, and the conduit communicates with a suctioning mechanism 150 via predetermined piping (not shown). A lower end of the adsorption pin 11PA comes into contact with the substrate WU, and an upper end of the adsorption pin 11PB comes into contact with the substrate WN. The substrate WU and the substrate WN are suctioned by the suctioning mechanism 150 via the conduit and the inner tube. Because of this, the substrate WU and the substrate WN are adsorbed to the adsorption pins 11PA and 11PB respectively. The adsorption pins 11PA and 11PB are configured to be able to move in the up-down direction individually.

Each of the upper chuck 11A and the lower chuck 11B includes a chuck unit drive mechanism 140. Each of the upper chuck 11A and the lower chuck 11B can be moved in the up-down direction by the chuck unit drive mechanism 140. Also, each of the adsorption pins 11PA and 11PB can also be moved in the up-down direction by the chuck unit drive mechanism 140.

The chuck unit drive mechanism 140 is an actuator that includes an unshown motor or the like. The chuck unit drive mechanism 140 controls an operation in the up-down direction of the chuck unit 11 and the adsorption pins 11PA and 11PB in accordance with an instruction from the control unit 50. Because of this, each of the substrate WU and the substrate WN can move individually in the up-down direction in a state adsorbed to the adsorption pins 11PA and 11PB respectively.

The separating arm unit 12a causes a blade 12H to enter the bonded portion T of the bonded substrate W. The separating arm unit 12a is disposed on an outer side of the chuck unit 11. For example, two separating arm units 12a are disposed to be opposing across the chuck unit 11. The separating arm unit 12a has a blade moving stand 12D, an arm portion 12Sa, and the blade 12H.

An unshown rail that extends toward the center of the chuck unit 11 is provided on an upper face 12DM of the blade moving stand 12D. A stand portion 12DD is connected to the rail. Also, the arm portion 12Sa, which extends toward the center of the chuck unit 11, is connected to the stand portion 12DD.

The blade moving stand 12D includes a separating arm unit drive mechanism 160. The stand portion 12DD can be caused to advance toward and retreat from the center of the chuck unit 11 by the separating arm unit drive mechanism 160. Also, the arm portion 12Sa can also advance toward and retreat from the center of the chuck unit 11 in accompaniment to this kind of movement of the stand portion 12DD.

The blade moving stand 12D can be caused to move in the up-down direction by the separating arm unit drive mechanism 160. The arm portion 12Sa can also move in the up-down direction in accompaniment to movement in the up-down direction of the blade moving stand 12D.

The separating arm unit drive mechanism 160 is an actuator that includes an unshown motor or the like. The separating arm unit drive mechanism 160 controls a movement toward the center of the chuck unit 11, and an operation in the up-down direction, of the blade moving stand 12D in accordance with an instruction from the control unit 50.

The blade 12H, which extends toward the center of the chuck unit 11, is connected to an end portion of the arm portion 12Sa. Detailed configurations of the arm portion 12Sa and the blade 12H will be described hereafter.

The cleaving position adjustment side camera 13 is, for example, an image sensor. The cleaving position adjustment side camera 13 is provided in an outer periphery of the chuck unit 11. The cleaving position adjustment side camera 13 images the bonded portion T of the bonded substrate W, and transmits a captured image to the control unit 50.

The separating arm unit drive mechanism 160, in accordance with an instruction from the control unit 50, adjusts the position in the up-down direction of the blade moving stand 12D in such a way that a difference in height between a position of the bonded portion T detected based on the captured image and the blade 12H becomes zero. Because of this, the blade 12H and the arm portion 12Sa can enter toward the bonded portion T of the bonded substrate W.

The fluid recovery pan 14 recovers a fluid discharged from the blade 12H. The fluid recovery pan 14 is provided below the chuck unit 11 and the separating arm unit 12a, and is connected to an unshown drainage line. Details of the fluid F will be described hereafter.

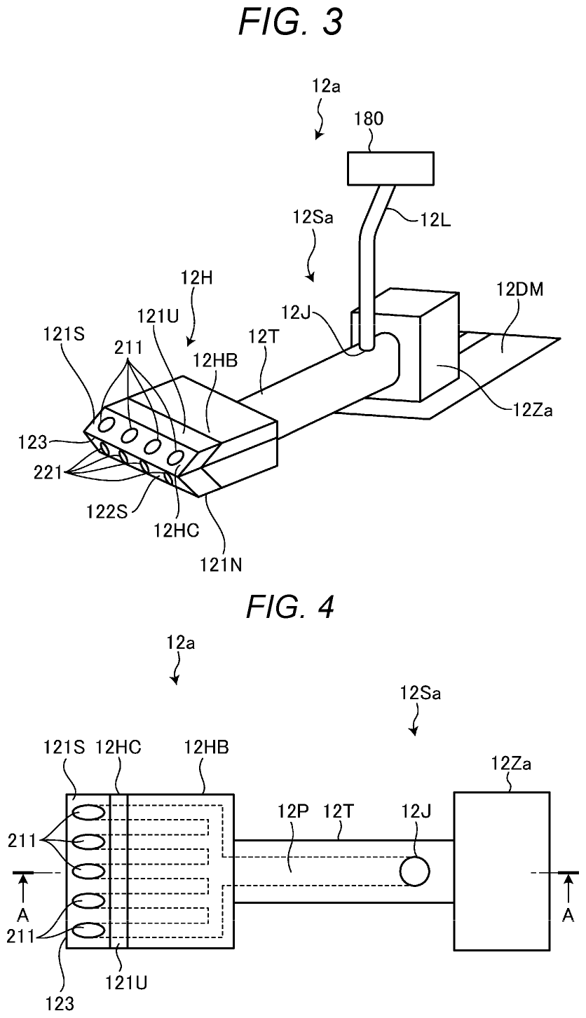

Using FIGS. 3 to 5, details of the arm portion 12Sa and the blade 12H will be described.

FIG. 3 is a perspective view showing an example of a configuration of one portion of the separating arm unit 12a provided in the semiconductor device manufacturing device 1 according to the embodiment. FIG. 4 is a top view showing an example of a configuration of one portion of the separating arm unit 12a provided in the semiconductor device manufacturing device 1 according to the embodiment. For ease of description, a depiction of a configuration of one portion of the arm separating unit 12a, such as the blade moving stand 12D, is omitted.

As shown in FIGS. 3 and 4, the blade 12H acting as a separating member is a plate-form member provided on a leading end of the arm portion 12Sa. The blade 12H can be interposed between the substrate WU and the substrate WN by the arm portion 12Sa entering toward the bonded portion T. Because of this, the bonded portion T is cleaved, and the bonded substrate W is divided into the substrate WU and the substrate WN. The blade 12H has a main body portion 12HB and a leading end tip portion 12HC.

The main body portion 12HB is of, for example, metal. The main body portion 12HB is connected to the leading end of the arm portion 12Sa. Also, the leading end tip portion 12HC is provided on an end portion of the main body portion 12HB on a side opposite to that of the arm portion 12Sa.

The leading end tip portion 12HC is a member that can come into contact with the bonded portion T. The leading end tip portion 12HC is of a resin such as Teflon (registered trademark). Because of this, the leading end tip portion 12HC can come into contact with the bonded portion T relatively flexibly.

Instead of a resin such as Teflon (registered trademark), a metal or the like having flexible properties, for example, may be used as a material of the leading end tip portion 12HC.

The leading end tip portion 12HC has an upper face 121U as a first face that can oppose the substrate WU and a lower face 121N as a second face that can oppose the substrate WN. An inclined face 121S is formed on the upper face 121U as a first inclined face that descends from the upper face 121U toward a direction of entry into the bonded portion T. Also, an inclined face 122S is formed on the lower face 121N as a second inclined face that ascends from the lower face 121N toward a direction of entry into the bonded portion T. The inclined face 121S and the inclined face 122S are continuous in a leading end portion 123. In other words, the inclined face 121S and the inclined face 122S neighbor each other in the leading end portion 123. An angle formed by the inclined face 121S and the inclined face 122S neighboring each other in the leading end portion 123 is, for example, 90° or less. Because of this, the blade 12H can easily be interposed between the substrate WU and the substrate WN.

Ejection holes 211 and 221 are formed in the inclined faces 121S and 122S respectively of the leading end tip portion 12HC as aperture portions that can discharge the fluid F. A multiple of the ejection holes 211 are formed in an upper face of the inclined face 121S aligned in a direction that intersects the direction of entry into the bonded portion T. Also, a multiple of the ejection holes 221 are formed in an upper face of the inclined face 122S aligned in a direction that intersects the direction of entry into the bonded portion T.

The fluid F is an inert gas such as compressed air, or a liquid such as pure water. When the arm portion 12Sa enters the bonded portion T, the fluid F is discharged toward the bonded portion T from each of the ejection holes 211 and 221. Because of this, the fluid F is interposed between the bonded portion T and the leading end tip portion 12HC, meaning that direct contact between the bonded portion T and the leading end tip portion 12HC decreases.

The arm portion 12Sa supports the blade 12H, and enters toward the bonded portion T. The arm portion 12Sa has a blade shaft 12T and a cleaving load detection monitor 12Za.

The blade shaft 12T is a rod-form member of metal or the like. Piping 12P that extends in a longitudinal direction is incorporated in the blade shaft 12T. One end portion of the piping 12P communicates with the ejection holes 211 and 221 of the leading end tip portion 12HC. Also, one end portion of piping 12L is connected to an other end portion of the piping 12P via an aperture portion 12J disposed in a side face of the blade shaft 12T. As is also shown in FIG. 2, an other end portion of the piping 12L is connected to a fluid control mechanism 180.

The fluid control mechanism 180 includes, for example, an unshown supply unit that can control pressure. The control unit 50 controls a supply of the fluid F by controlling the fluid control mechanism 180.

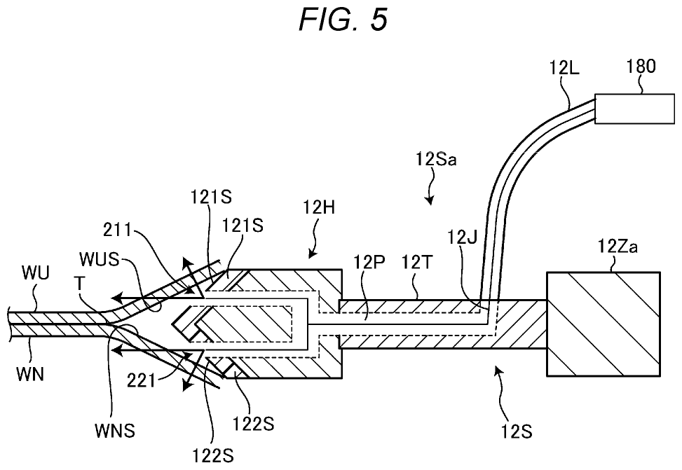

FIG. 5 is a drawing illustrating an aspect such that the blade 12H provided in the semiconductor manufacturing device 1 according to the embodiment is interposed in the bonded portion T. FIG. 5 is an A-A sectional view of FIG. 4. Also, arrows in FIG. 5 schematically show one example of directions in which the fluid F is discharged.

When the blade 12H is interposed between the substrate WU and the substrate WN, the inclined face 121S of the blade 12H opposes a face WUS of the substrate WU, and the inclined face 122S of the blade 12H opposes a face WNS of the substrate WN, as shown in FIG. 5. On the fluid F being supplied at a predetermined rate from the fluid control mechanism 180, the fluid F is discharged in, for example, the directions indicated by the arrows from each of the ejection holes 211 and 221 via the piping 12L and the piping 12P.

Because of this, the face WUS of the substrate WU receives a force in a direction such that the face WUS is separated from the substrate WN owing to the fluid F ejected from the ejection hole 211. Also, the face WNS of the substrate WN receives a force in a direction such that the face WNS is separated from the substrate WU owing to the fluid F ejected from the ejection hole 221. Owing to this kind of ejection of the fluid F, the bonded portion T is more efficiently cleaved, with no damage such as scratching.

Also, the bonded portion T of the bonded substrate W receives a force in the direction of entry of the blade shaft 12T owing to the fluid F. Owing to this kind of ejection of the fluid F, the bonded portion T is more effectively cleaved, with no damage such as scratching.

The cleaving load detection monitor 12Za, which acts as a sensing unit, has, for example, a piezoelectric element. The cleaving load detection monitor 12Za is connected to an end portion of the blade shaft 12T. The cleaving load detection monitor 12Za detects a signal caused by a change in pressure applied to the blade 12H when the blade shaft 12T enters the bonded portion T. The cleaving load detection monitor 12Za transmits a result of the detection to the control unit 50.

Depending on conditions and the like when being bonded, the bonded portion T may be partially strongly bonded. In such a case, the bonded portion T may fail to be cleaved by a predetermined force. The cleaving load detection monitor 12Za detects a signal indicating, for example, a rise in resistance of the blade shaft 12T. The cleaving load detection monitor 12Za transmits a result of the detection to the control unit 50. The control unit 50 controls the fluid control mechanism 180 based on the detection result, thereby causing the amount of the fluid F ejected to increase. Because of this, the fluid F is ejected from the ejection holes 211 and 221 at a still higher pressure. As a result of this, the bonded portion T is stably cleaved.

The control unit 50 may control the chuck unit drive mechanism 140 based on the detection result received from the cleaving load detection monitor 12Za, thereby adjusting a movement in the up-down direction of the upper chuck 11A, the lower chuck 11B, and the adsorption pins 11PA and 11PB. By so doing, for example, a force in the upward direction is applied to the substrate WU, and a force in the downward direction is applied to the substrate WN. That is, forces are applied to the substrate WU and the substrate WN in directions such that the substrate WU and the substrate WN are separated from each other. As a result of this, the bonded portion T is more efficiently cleaved.

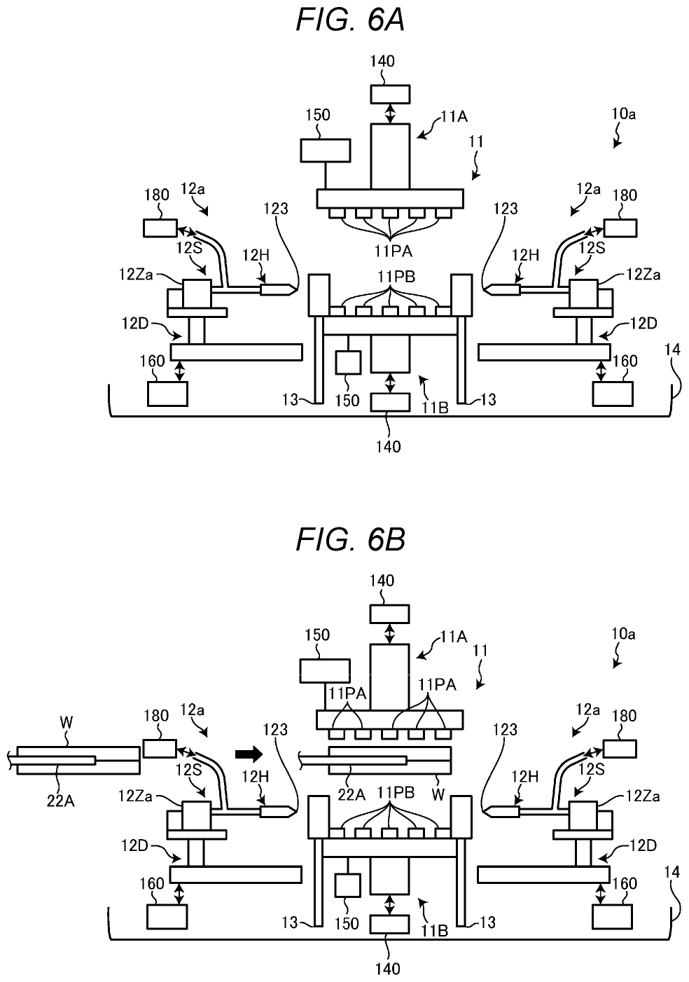

Next, using FIGS. 6 to 10, a process of dividing the bonded substrate W using the semiconductor manufacturing device 1 will be described. FIGS. 6 to 10 are drawings sequentially showing an example of one portion of procedure of a process of dividing the bonded substrate W using the semiconductor manufacturing device 1 according to the embodiment.

FIG. 6 is side views schematically showing a flow as far as the bonded substrate W being transferred to the processing chamber 10a. As shown in FIG. 6A, the upper chuck 11A of the chuck unit 11 is disposed above the separating arm unit 12a by the chuck unit drive mechanism 140 in the processing chamber 10a in an initial state.

As shown in FIG. 6B, the bonded substrate W is transferred to a space between the upper chuck 11A and the separating arm unit 12a by the transfer arm 22A.

Prior to the aforementioned transfer, the bonded substrate W is transferred from the port 30 to the transfer chamber 20, and from the transfer chamber 20 to the pre-alignment unit 21, by the transfer arm 22A. Further, after a deviation of a central position is corrected in the pre-alignment unit 21, the bonded substrate W is transferred to the processing chamber 10a by the transfer arm 22A.

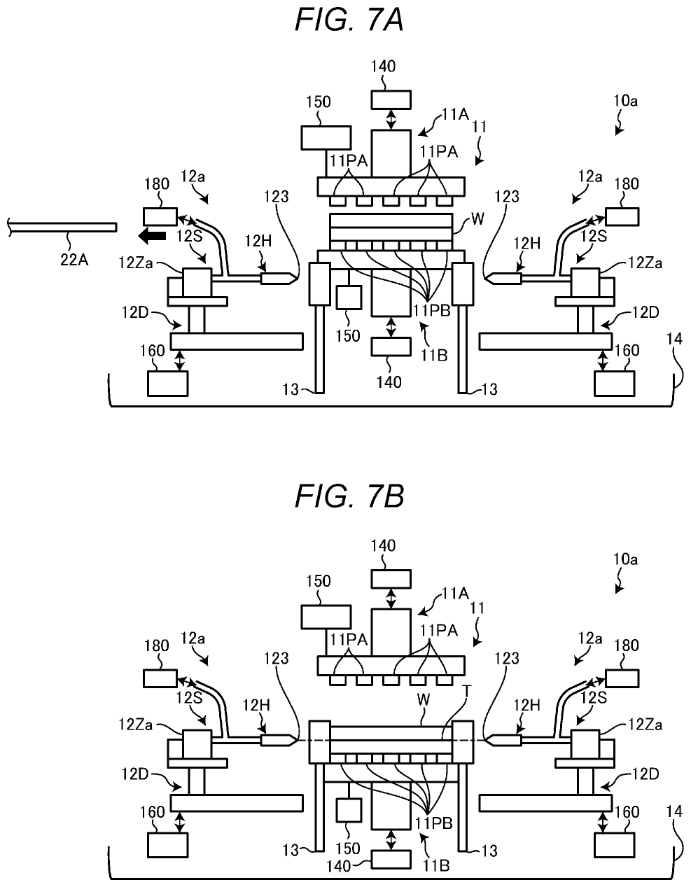

FIG. 7 is side views schematically showing a flow from the bonded substrate W being transferred to the processing chamber 10a to a positioning of the bonded substrate W and the blade shaft 12T being carried out. As shown in FIG. 7A, the lower chuck 11B is raised until the adsorption pin 11PB provided on an upper face of the lower chuck 11B and the bonded substrate W come into contact. On the bonded substrate W coming into contact with the adsorption pin 11PB of the lower chuck 11B, the bonded substrate W is adsorbed to the adsorption pin 11PB by the suctioning mechanism 150. Subsequently, the transfer arm 22A retreats processing chamber 10a. By so doing, the transfer of the bonded substrate W from the transfer arm 22A to the lower chuck 11B ends.

On the lower chuck 11B descending to an original position, as shown in FIG. 7B, positioning in the up-down direction of the blade shaft 12T is carried out. This positioning may be carried out based on a captured image acquired using the cleaving position adjustment side camera 13. For example, the separating arm unit drive mechanism 160 adjusts the position of the blade moving stand 12D in such a way that a difference in height between a position of the bonded portion T detected based on the captured image and the leading end portion 123 of the blade 12H becomes zero.

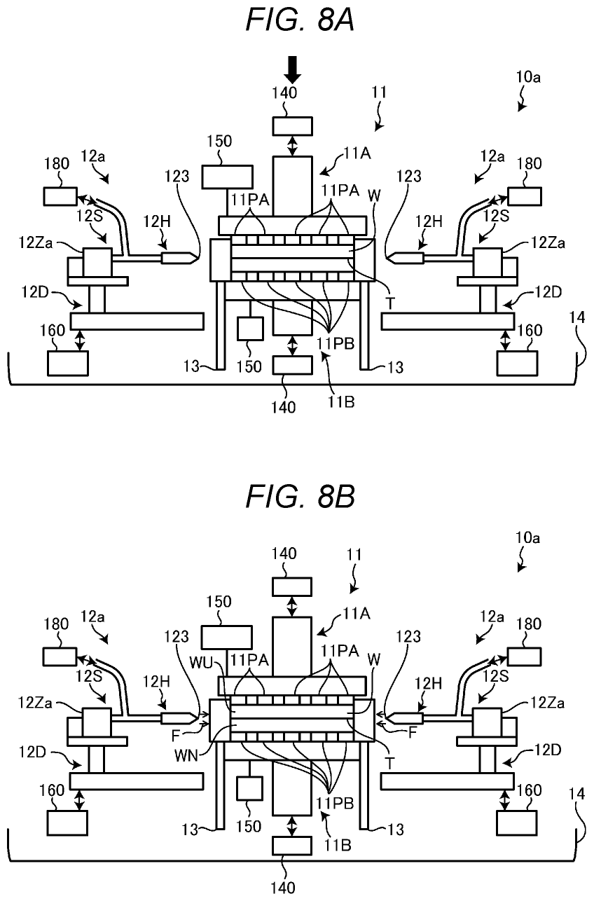

FIG. 8 is side views schematically showing a flow from the bonded substrate W being adsorbed to the chuck unit 11 of the processing chamber 10a to a process of dividing the bonded substrate W being started. As shown in FIG. 8A, the upper chuck 11A descends until the adsorption pin 11PA provided on a lower face of the upper chuck 11A and an upper face of the bonded substrate W come into contact. On the upper face of the bonded substrate W coming into contact with the adsorption pin 11PA of the upper chuck 11A, the bonded substrate W is adsorbed to the adsorption pin 11PA by the suctioning mechanism 150.

As shown in FIG. 8B, the fluid control mechanism 180 starts a discharge of the fluid F from the blade 12H. Further, in FIG. 8B, the chuck unit drive mechanism 140 causes an upward movement of the upper chuck 11A to start, and simultaneously causes a downward movement of the lower chuck 11B to start. Because of this, a force such that the substrate WU is pulled upward works on the substrate WU on the upper side of the bonded substrate W, and a force such that the substrate WN is pulled downward works on the substrate WN on the lower side. Also, the separating arm unit drive mechanism 160 causes a movement of each blade shaft 12T toward the bonded portion T to start. The discharged fluid F is recovered by the fluid recovery pan 14, and discharged from the processing chamber 10a.

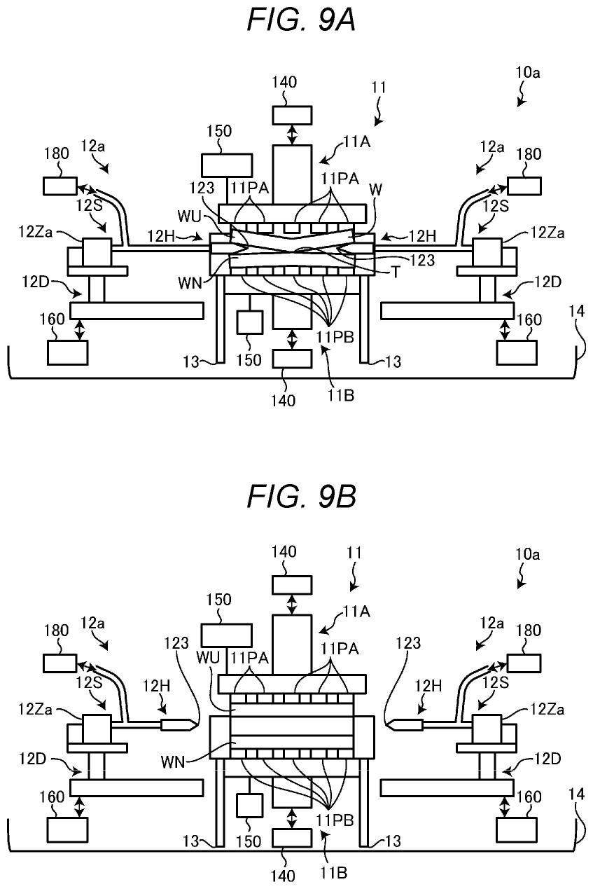

FIG. 9 is side views schematically showing a flow from the blade shaft 12T of the processing chamber 10a starting to move toward the bonded substrate W until finishing division and returning to the original position. On the leading end portion 123 of the blade 12H being pressed against the bonded portion T of the bonded substrate W, a gap is formed in the bonded portion T. The blade shaft 12T is pushed into this gap, and further moves toward a center of the bonded substrate W. As a result of this, the substrate WU and the substrate WN of the bonded substrate W are separated from a peripheral edge portion thereof.

At this point, the cleaving load detection monitor 12Za detects a signal caused by a change in pressure applied to the blade 12H when the blade shaft 12T enters the bonded portion T. On the cleaving load detection monitor 12Za detecting the signal, the separating arm unit drive mechanism 160 stops the movement of the blade shaft 12T. Further, the fluid control mechanism 180 adjusts the amount of the fluid F discharged. Next, the separating arm unit drive mechanism 160 restarts the movement of the blade shaft 12T. In this way, the substrate WU and the substrate WN can be stably divided.

On the blade shaft 12T further moving toward the center of the bonded substrate W, the substrate WU and the substrate WN separate in a portion near the center of the bonded substrate W too. Further, on the substrate WU and the substrate WN being further caused to move, the bonded substrate W divides in a central portion too. As a result of this, the substrate WU on the upper side is lifted in an upward direction by the upper chuck 11A, as shown in FIG. 9B. Also, the substrate WN on the lower side is pulled in a downward direction by the lower chuck 11B. In this way, the division of the bonded substrate W is completed. Continuing, the blade shaft 12T retreats, and returns to the original position.

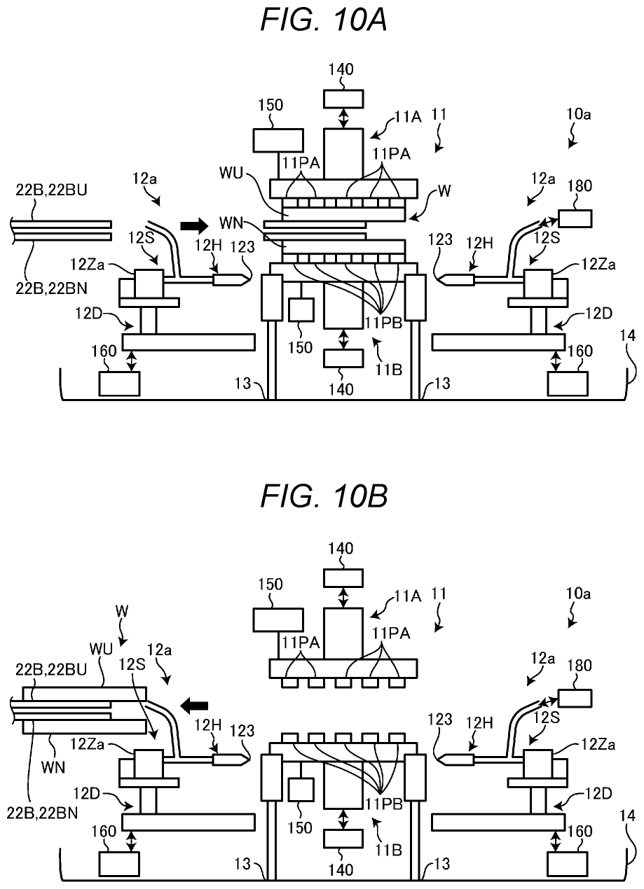

FIG. 10 is side views schematically showing a flow as far as the bonded substrate W being transferred from the processing chamber 10a. As shown in FIG. 10A, the transfer arm 22B enters a space between the upper chuck 11A and the separating arm unit 12a. The transfer arm 22B has two arms, 22BU and 22BN, in the up-down direction. The upper arm 22BU includes an unshown substrate adsorption mechanism on an upper side, and the lower arm 22BN includes an unshown substrate adsorption mechanism on a lower side.

On the upper chuck 11A descending, and the substrate WU adsorbed by the upper chuck 11A coming into contact with the arm 22BU, the arm 22BU adsorbs the substrate WU. Next, the adsorption by the upper chuck 11A is stopped, and the substrate WU is transferred from the upper chuck 11A to the arm 22BU. Also, on the lower chuck 11B rising, and the substrate WN remaining on the lower chuck 11B coming into contact with the arm 22BN, the arm 22BN adsorbs the substrate WN. Next, the adsorption by the lower chuck 11B is stopped, and the substrate WN is transferred from the lower chuck 11B to the arm 22BN.

Subsequently, the process of dividing the bonded substrate W in the semiconductor manufacturing device 1 is ended by the transfer arm 22B carrying out the substrate WU and the substrate WN, as shown in FIG. 10B.

### Comparative Example

At this point, a semiconductor manufacturing device of a comparative example will be described. The semiconductor manufacturing device of the comparative example is such that a bonded substrate may be divided by a sharp blade being inserted between bonded faces of the bonded substrate. However, the semiconductor manufacturing device of this kind of comparative example is such that the blade comes into direct contact with the bonded substrate, because of which damage such as scratching or cracking may be caused to the bonded substrate. Also, a substrate on an upper side of the bonded substrate may descend due to gravitational force in accompaniment to being detached, whereby contact between the substrate and the blade is accelerated.

Also, a semiconductor manufacturing device of another comparative example is such that a bonded substrate may be divided by a liquid being discharged against bonded faces of the bonded structure. However, the semiconductor manufacturing device of this kind of comparative example is such that although there is little damage to the bonded substrate, it may be difficult to efficiently divide the bonded substrate.

### SUMMARY

The semiconductor manufacturing device 1 of the embodiment includes the blade 12H, which can be interposed between the substrate WU and the substrate WN. The inclined face 121S and the inclined face 122S, which descend in the direction of entry into the bonded portion T, are formed on the upper face 121U and the lower face 121N of the blade 12H, which oppose the substrate WU and the substrate WN respectively. The ejection holes 211 and 221, which can discharge the fluid F in the direction of entry into the bonded portion T, are formed in the inclined face 121S and the inclined face 122S. Because of this, the fluid F is interposed between the bonded portion T and the blade 12H, because of which direct contact between the bonded portion T and the blade 12H decreases. Also, owing to the ejection of the fluid F, each of the substrate WU and the substrate WN receives a force in a direction such that the substrate WU and the substrate WN are pulled away from each other. Because of this, the substrate WU and the substrate WN can be efficiently separated, while damage to the substrate WU and the substrate WN is restricted.

Also, the inclined face 121S and the inclined face 122S of the blade 12H of the embodiment are of a resin material such as Teflon (registered trademark). Because of this, damage to the substrate WU and the substrate WN can be restricted.

According to the semiconductor manufacturing device 1 of the embodiment, the arm portion 12Sa has the cleaving load detection monitor 12Za, which can detect pressure applied to the blade 12H when the blade shaft 12T enters the bonded portion T. The control unit 50 adjusts the amount of the fluid F discharged based on the result of the detection by the cleaving load detection monitor 12Za. Because of this, the bonded substrate W can be stably divided.

### Modification

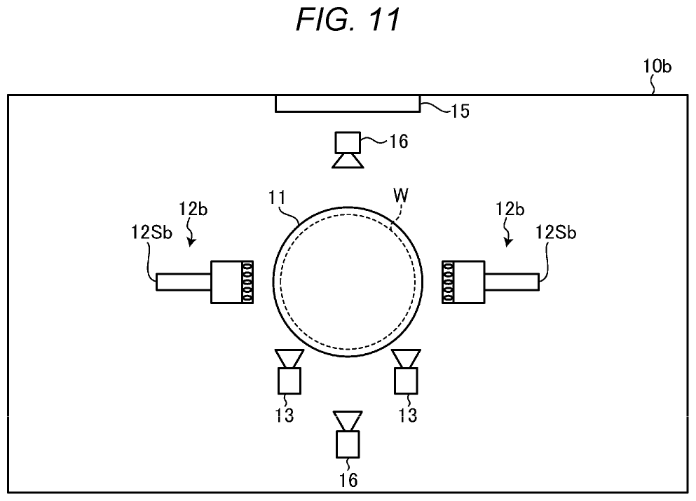

A semiconductor manufacturing device of a modification of the embodiment will be described, using FIG. 11. The semiconductor manufacturing device of the modification differs from the embodiment in that an arm portion 12Sb of a separating arm unit 12b does not have the cleaving load detection monitor 12Za, and in that the chuck unit 11 can move in a direction in which the separating arm unit 12b advances.

Hereafter, identical reference signs are allotted to configurations the same as those of the embodiment, and a description thereof may be omitted.

FIG. 11 is a top view showing one example of a configuration of a processing chamber 10b provided in the semiconductor manufacturing device according to the modification.

The processing chamber 10b has the chuck unit 11, the separating arm unit 12b, the cleaving position adjustment side camera 13, the loading port 15, and a cleaving load detection monitor 16, as shown in FIG. 11, and the fluid recovery pan 14. For ease of description, a depiction of the fluid recovery pan 14 is omitted.

The cleaving load detection monitor 16 acting as an imaging unit (imager) has, for example, an imaging element. The cleaving load detection monitor 16 is disposed in an outer periphery of the chuck unit 11. The cleaving load detection monitor 16 is disposed to be oriented in a direction that intersects directions in which the two separating arm units 12b, which are disposed oriented toward the center of the chuck unit 11, are oriented.

The chuck unit 11 is configured to be movable by the chuck unit drive mechanism 140 at a predetermined speed in a direction in which the arm portion 12Sb advances. Because of this, the cleaving load detection monitor 16 can image the bonded portion T from a peripheral edge of the bonded substrate W toward the center. The cleaving load detection monitor 16 acquires a captured image of the bonded portion T by imaging the bonded portion T.

The cleaving load detection monitor 16 transmits the acquired captured image to the control unit 50. The control unit 50 calculates a distance between the unshown substrate WU and substrate WN by carrying out an image analysis based on the captured image. The control unit 50 controls the fluid control mechanism 180 based on the calculated distance, thereby adjusting the amount of the fluid F discharged. For example, the control unit 50 recognizes that the distance between the substrate WU and the substrate WN is shorter than an assumed distance. Therefore, the control unit 50 controls the fluid control mechanism 180 based on a result of the recognition, thereby causing the amount of the fluid F discharged to increase. By so doing, the fluid F is discharged from the ejection holes 211 and 221 at a still higher pressure. As a result of this, the bonded portion T is stably cleaved. Because of this, the bonded portion T is stably cleaved.

At this time, the cleaving load detection monitor 16 may move in the direction in which the arm portion 12Sb advances instead of the chuck unit 11.

Also, although the cleaving load detection monitor 16 is described as having an imaging element, this is not limiting. The cleaving load detection monitor 16 may detect the substrate WU and the substrate WN using, for example, laser light.

According to the semiconductor manufacturing device of the modification, other advantages the same as those of the semiconductor manufacturing device 1 of the embodiment are achieved.

While a certain embodiment has been described, this embodiment has been presented by way of example only, and is not intended to limit the scope of the disclosure. Indeed, the novel embodiment described herein may be embodied in a variety of other forms; furthermore, various omissions, substitutions and changes in the form of the embodiment described herein may be made without departing from the spirit of the disclosure. The accompanying claims and their equivalents are intended to cover such forms or modifications as would fall within the scope and spirit of the disclosure.

What is claimed is:

1. A semiconductor manufacturing device, comprising:
a substrate support unit configured to support a bonded substrate including two substrates bonded to each other;
an arm portion disposed adjacent the substrate support unit and configured to move toward and from a bonded portion of the bonded substrate; and
a separating member provided on an end of the arm portion and configured to separate the two substrates by the arm portion entering the bonded portion, wherein the separating member includes a first inclined face and a second inclined face that extend toward the bonded portion and are respectively extended from end portions of first and second faces of the separating member, wherein
the separating member further includes an aperture portion configured to discharge a fluid toward the bonded portion.

2. The semiconductor manufacturing device according to claim 1, wherein
the first inclined face and the second inclined face are continuous in an end portion of the separating member.

3. The semiconductor manufacturing device according to claim 1, wherein the arm portion has a sensor unit configured to detect a change in pressure around the bonded portion, and
the semiconductor manufacturing device further comprises a controller configured to adjust an amount of the fluid discharged based on a detection result provided by the sensing unit.

4. The semiconductor manufacturing device according to claim 1, further comprising:
an imaging unit configured to acquire a captured image of the bonded portion; and
a controller configured to adjust an amount of the fluid discharged based on a distance between the two substrates calculated based on the captured image.

5. The semiconductor manufacturing device according to claim 1, wherein the first and second inclined faces each include a resin material.

6. A separating member used in a semiconductor manufacturing device configured to separate a bonded substrate with two substrates bonded to each other, wherein
the separating member is provided on an end of an arm portion that is disposed around a substrate support unit supporting the bonded substrate and is configured to move toward and from a bonded portion of the bonded substrate, wherein
the separating member includes a first inclined face and a second inclined face that extend toward the bonded portion and are respectively extended from end portions of first and second faces of the separating member, and
an aperture portion configured to discharge a fluid toward the bonded portion.

7. The separating member according to claim 6, wherein the first inclined face and the second inclined face are continuous in an end portion of the separating member.

8. The separating member according to claim 6, wherein an angle formed between the first inclined face and the second inclined face is less than about 90°.

9. The separating member according to claim 6, wherein the first inclined face descends from the first face toward the bonded portion.

10. The separating member according to claim 6, wherein the second inclined face ascends from the second face toward the bonded portion.

11. The separating member according to claim 6, wherein the aperture portion includes a plurality of ejection holes.

12. The separating member according to claim 11, wherein the plurality of ejection holes include at least one ejection hole formed in each of the first inclined face and the second inclined face.
